(19) United States
(12) Patent Application Publication
(10) Pub. No.: US 2002/0117714 A1
(43) Pub. Date: Aug. 29, 2002

(54) High voltage MOS transistor

(75) Inventor: Francois Hebert, San Mateo, CA (US)

Correspondence Address: FISH & NEAVE, 1251 AVENUE OF THE AMERICAS, 50TH FLOOR, NEW YORK, NY, 10020-1105, US

(73) Assignee: LINEAR TECHNOLOGY CORPORATION, Milpitas, CA

(21) Appl. No.: 09/796,495

(22) Filed: Feb. 28, 2001

(51) Int. Cl. H01L 21/8238; H01L 21/336; H01L 29/76; H01L 29/94; H01L 31/062; H01L 31/113; H01L 31/119

(52) U.S. Cl. 257/339; 438/212; 438/268

(57) ABSTRACT

The present invention provides high voltage MOS transistors that have a high breakdown voltage and a low specific ON resistance in the drain. High voltage MOS transistors of the present invention include a source region and a drain region formed in an body region. The drain region includes a low doped extension region, a higher doped base region, and a more highly doped type region. The extension region of the drain extends toward the gate, further than the base region. The extension region increases the breakdown voltage in the drain near the gate where the electric field is high, because it has relatively low doping concentration. The base region also increases the breakdown voltage between the drain and the body because the base region has a lower doping concentration than the region.

### BACKGROUND OF THE INVENTION

The present invention relates to apparatus and methods for high voltage transistors. More specifically, the present invention relates to high voltage MOS field effect transistors with an increased breakdown voltage.

Many applications for semiconductor devices require MOS transistors that can operate with high voltages (e.g., greater than 40 volts) at their terminals. A high drain-to-body voltage in an MOS transistor can produce a large electric field that causes breakdown across a reversed biased PN junction. Breakdown causes undesirable current to flow between the drain and the body or between the drain and the source of the transistor. Breakdown can also cause device failure.

One previously known high voltage PMOS transistor 10 is shown in FIG. 1A. Transistor 10 has a source formed by P+ region 15, a body formed by N-type epitaxy or N-type well 12, and a drain formed in part by P+ region 11. Transistor 10 also has P-type base region 13 which is an extension of the drain region of transistor 10. P-base 13 has a lower P-type doping concentration than highly doped P+ drain region 11. P-base 13 is formed by ion implantation after gate 14 is patterned. P-base 13 is optimized for use in making the base region of NPN bipolar junction transistors, and P-base 13 diffusion is usually shallow with a relatively high surface concentration. P-base 13 is not optimized for P-type extensions of the drain region in PMOS transistors. The breakdown voltage in transistor 10 is lower than needed for certain high voltage applications.

Another previously known high voltage PMOS transistor 20 is shown in FIG. 1B. Transistor 20 includes gate 21, thick field oxide 22, P+ source region 24, and P+ drain region 25. Transistor 20 also includes P-field region 23 which is part of the drain and is self-aligned to field oxide 22. In transistor 20, thick field oxide 22 is formed over P-type field (also called P-type channel stop) region 23 as shown in FIG. 1B. Thick field oxide 22 reduces the electric field in P-field region 23 below gate 21. However, thick field oxide 22 causes transistor 20 to have undesirably large device dimensions. Thick field oxide 22 also increases the ON resistance between the drain-to-source (R_{DS-ON}) which is also undesirable, because field oxide 22 encroaches down into P-field region 23.

Another previous known high voltage PMOS transistor 30 is shown in FIG. 1C. Transistor 30 includes gate 31, P+ source region 35, highly doped P+ drain region 33, N-well body region 34, and P-drift region 32 which forms an extension of the drain of transistor 30. P-drift region 32 is formed after gate 31. The P-type dopant implant used to form P-drift region 32 should not penetrate through the gate electrode. Also, the thermal budget after gate 31 is formed is limited. Therefore, P-drift region 32 is shallow, which causes an undesirably low breakdown voltage. The PN junction between N-well 34 and highly doped P+ region 33 also causes an undesirably low breakdown voltage.

It would therefore be desirable to provide a high voltage MOS transistor that has a high breakdown voltage.

It would also be desirable to provide a high voltage MOS transistor that has a reduced specific ON resistance in the drain.

It would also be desirable to provide a structure which is self-aligned to maintain manufacturability.

### SUMMARY OF THE INVENTION

It is therefore an object of the present invention to provide a high voltage MOS transistor that has a high breakdown voltage.

It is also an object of the present invention to provide a high voltage MOS transistor that has a reduced specific ON resistance in the drain.

It would also be desirable to provide a structure which is self-aligned to maintain manufacturability.

The present invention provides high voltage MOS transistors that have a high breakdown voltage and a low specific ON resistance in the drain. High voltage MOS transistors of the present invention include a source region and a drain region that are formed in semiconductor on opposite sides of a gate. The drain region includes a low doped extension region, a higher doped base region, and a more highly doped contact region.

The extension region is masked in part by the gate so that the drain is self-aligned with the gate. The extension region overlaps the base region and the contact region. The base region is spaced away from the gate. The extension region of the drain extends beyond the base region underneath the gate. Thus, the drain extension region links the base region and the contact region to a region of semiconductor under the gate.

The extension region increases the breakdown voltage in the drain near the gate where the electric field is high, because it has relatively low doping concentration. The base region is deeper than the extension region and the contact region. The base region provides for an increased breakdown voltage between the drain and the body region, because it has a lower doping concentration than the contact region.

The base region reduces the specific ON resistance in the drain, because it increases the net doping concentration in a portion of the drain region between the contact region and the gate. Standard steps used in low voltage CMOS and BiCMOS processes may be used to form MOS transistors of the present invention. MOS transistors of the present invention include PMOS and NMOS transistors.

### BRIEF DESCRIPTION OF THE DRAWINGS

The above-mentioned objects and features of the present invention can be more clearly understood from the following detailed description considered in conjunction with the following drawings, in which the same reference numerals denote the same structural elements throughout, and in which:

FIGS. 1A-1C are illustrations of prior art high voltage PMOS transistors;

FIGS. 2A-2J are cross-sectional diagrams of process steps for the fabrication of an illustrative embodiment of high voltage PMOS transistors in accordance with the principles of the present invention;

FIGS. 3A-3C are cross-sectional diagrams of process steps for the fabrication of another illustrative embodiment of high voltage PMOS transistors in accordance with the principles of the present invention;

FIGS. 4A-4C are cross-sectional diagrams of process steps for the fabrication of another illustrative embodiment of high voltage PMOS transistors in accordance with the principles of the present invention;

FIG. 5 is a cross-sectional diagram of an illustrative embodiment of high voltage PMOS transistors with source/body and drain contacts in accordance with the principles of the present invention; and

FIG. 6 is a cross-sectional diagram of an illustrative embodiment of high voltage NMOS transistors with source/body and drain contacts in accordance with the principles of the present invention.

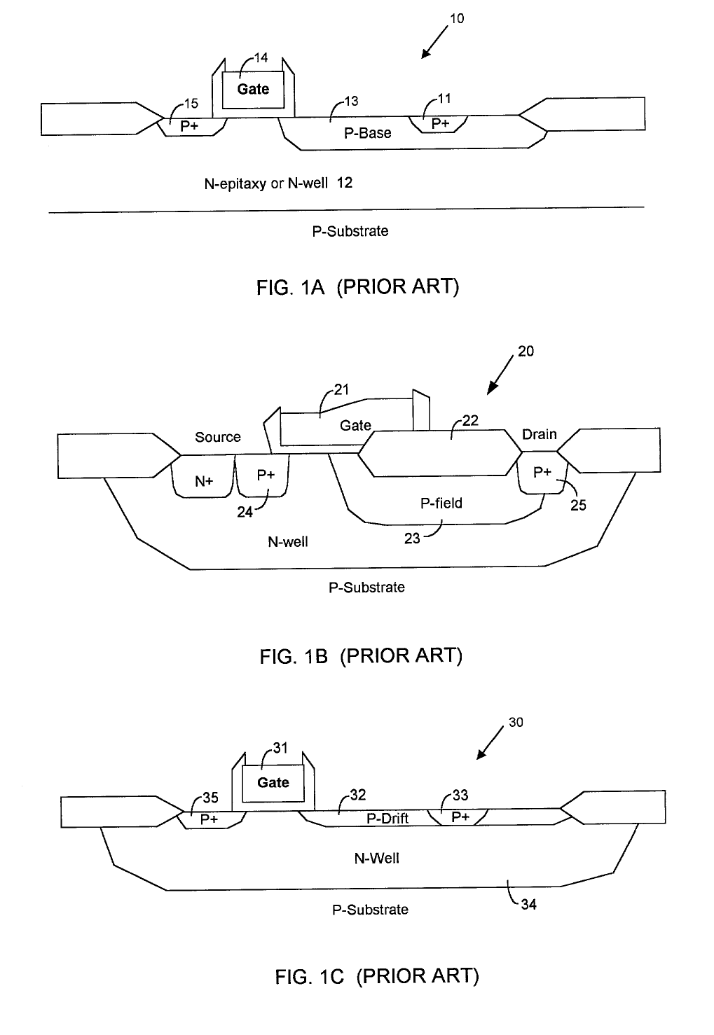

### DETAILED DESCRIPTION OF PREFERRED EMBODIMENTS

The present invention provides high voltage MOS transistors that have a high breakdown voltage, a and a reduced specific ON resistance in the drain. High voltage MOS transistors of the present invention have a drain region that includes a low doped extension region, a higher doped base region, and a more highly doped contact region. When a high voltage differential is applied between the gate and the drain, the electric field is high in the portion of the drain nearest to the gate. The extension region advantageously provides an increased breakdown voltage, because it is a low doped region that extends beyond the more highly doped base region under the gate. The base region also provides for an increased breakdown voltage, because it is deeper than the more highly doped contact region and has a greater radius of curvature.

The specific ON resistance in the drain where the base region and the extension region overlap is reduced, because the net doping concentration in this region is increased. The drain-to-source ON resistance of the transistor is advantageously reduced as a result. The three drain regions may be easily formed using standard steps in CMOS and BiCMOS processes. Therefore, no unique or custom equipment is required to form MOS transistors of the present invention. Also, the number of processes steps are minimized. MOS transistors of the present invention include PMOS and NMOS transistors. Transistors of the present invention may be formed as part of an integrated circuit.

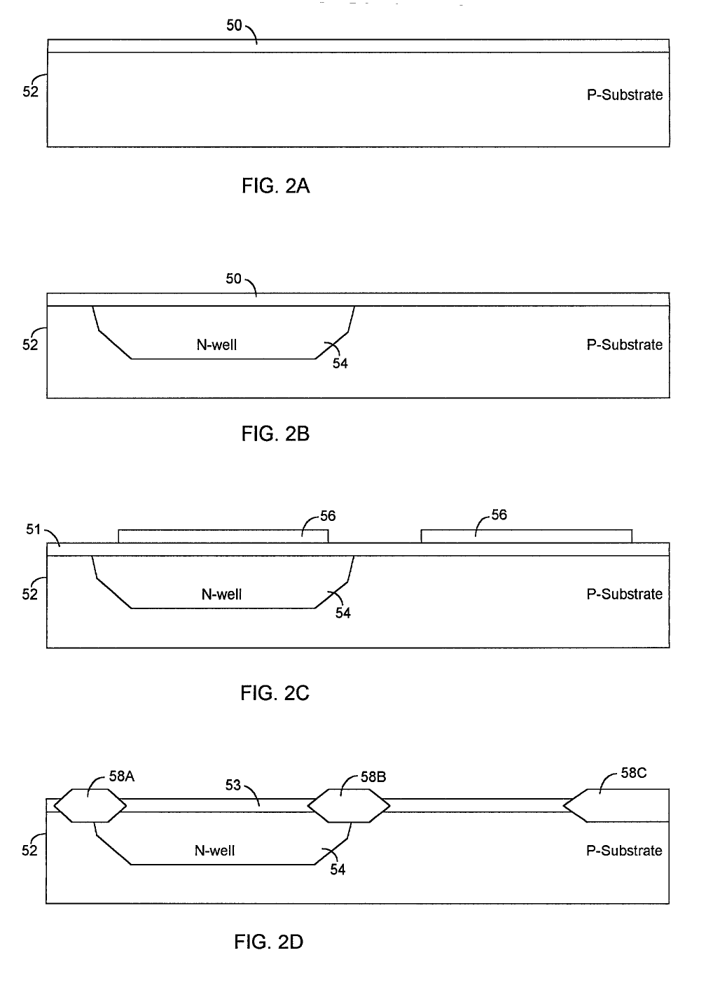

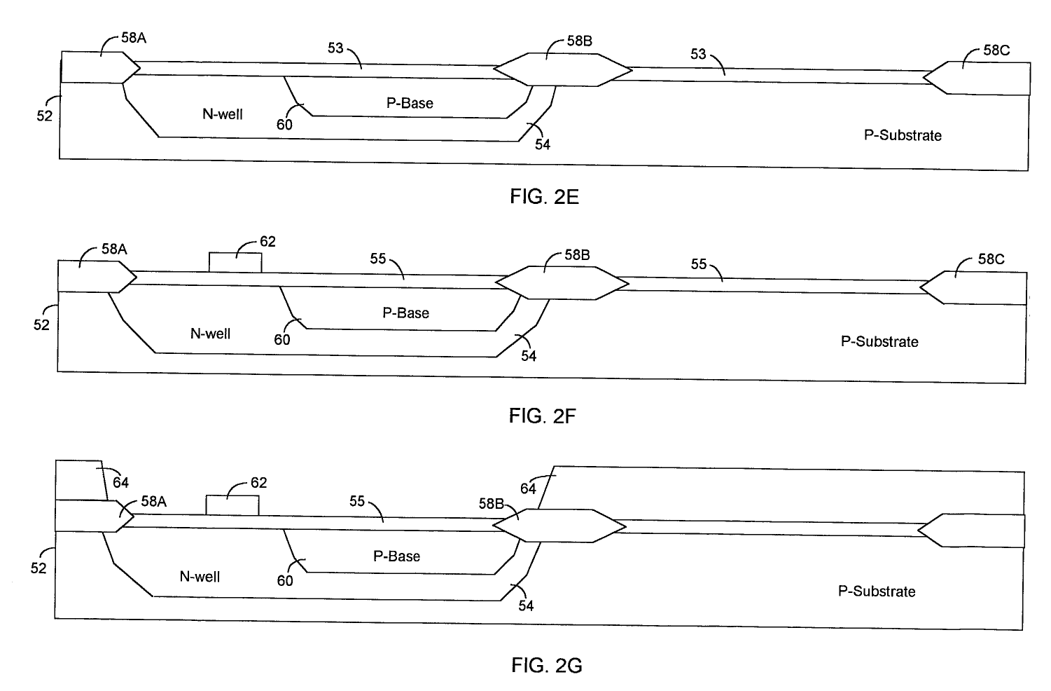

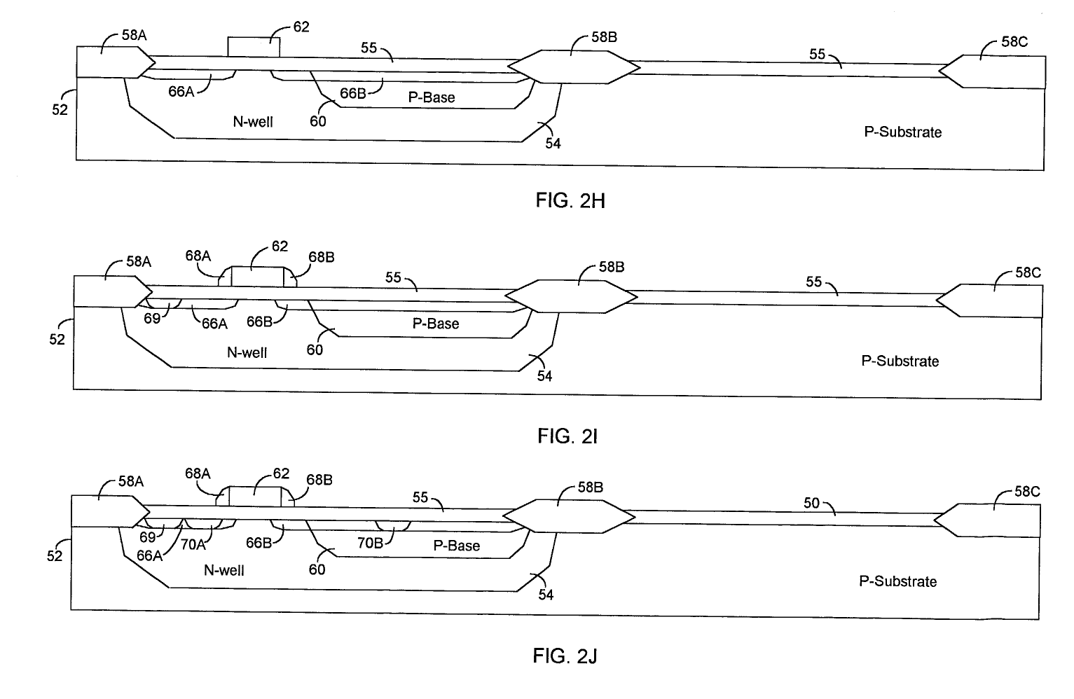

FIGS. 2A-2J are process steps for the fabrication of an illustrative embodiment of high voltage PMOS transistors of the present invention. In the first step of this embodiment, a screen oxide layer 50 is grown on top of P-type doped semiconductor (e.g., silicon) substrate wafer 52 as shown in FIG. 2A. A masking step is then performed to form N-well region 54 in substrate 52. Photoresist may be deposited and patterned on top of oxide layer 50 to mask the formation of region 54. If oxide layer 50 is thick (e.g., 10 kÅ thick and grown at 1150° C.), a portion of its thickness should be etched away so that dopants can be successfully implanted and diffused into wafer 52 to form N-well 54. If desired, layer 50 may be grown to have a thinner thickness (e.g., 250-500 Å) so that it is not necessary to etch a portion of its thickness to form N-well 54.

Subsequently, the wafer may be cleaned, and N-type implant dopant is implanted into substrate 52. The N-type dopants may, for example, have an implant dopant concentration in the range of 2×10¹² to 1×10¹³ dopants/cm². The photoresist is then removed from oxide layer 50. The N-type dopant is then driven into substrate 52 to form N-well region 54 as shown in FIG. 2B. Oxide layer 50 may then be removed from the top of substrate 52.

Another oxide layer 51 can be grown on top of substrate 52 as shown in FIG. 2C. Silicon nitride (Si₃N₄) can be deposited to form layer 56 on top of layer 51 using, for example, low pressure chemical vapor deposition (LP-CVD). Silicon nitride is used to mask the formation of thick field oxide regions between transistors. Oxide layer 51 prevents stress from the silicon nitride from inducing defects in the silicon wafer. Lithography is performed on silicon nitride layer 56 through selective masking and etching to form the patterned regions of layer 56 shown in FIG. 2C. The masking may be performed using photoresist. Subsequent to etching layer 56, the photoresist is removed, and the wafer may be cleaned.

After silicon nitride layer 56 is defined, wafer 52 is inserted into an oxidation furnace, and thick oxide regions such as oxide regions 58A-58C are grown in between the regions of nitride layer 56 using a process of local oxidation of silicon (LOCOS) as shown in FIG. 2D. Oxide regions 58A-58C provide isolation between devices formed in substrate 52. Oxide regions 58A-58C may, for example, be grown to a thickness of in the range of 5000 Å to 20,000 Å (angstroms). A specific example for the thickness of oxide region 58A-58C is 10,000 Å. A thin oxide layer may form over nitride 56. However, nitride layer 56 prevents oxidation over most of N-well 54. After the oxidation step, nitride layer 56 may be removed using, for example, hot phosphoric acid or a plasma etch that stops on oxide layer 51. Oxide layer 51 may then be removed, and another sacrificial oxide layer 53 can be grown on top of wafer 52 as shown in FIG. 2D. Oxide layer 53 may be grown to a thickness of, for example, 300-800 Å.

In the next process step, lithography can be performed using photoresist as a mask to form P-base region 60. P-type dopant can then be implanted into substrate 52, for example, at an implant dose in the range of 5×10¹² to 6×10¹³ dopants/cm² and at an energy in the range of 50 to 180 KeV. In a specific example, P-type dopant may be implanted at a dose of 2×10¹³ dopants/cm² at an energy of 160 KeV. The photoresist can then be removed, and the wafer may be cleaned. A thermal anneal step is then performed so that the P-type dopant diffuses down into N-well 54 to form P-base region 60 as shown in FIG. 2E. For example, the anneal may be performed at a temperature in the range of 800-1100° C. for 30 minutes to 1½ hours using Nitrogen ambient gas. A specific example is 1050° C. for 1½ hours. P-type dopant in P-base 60 may, for example, be diffused down to a depth in the range of 0.4 to 1.0 microns. P-base region 60 can be formed using process steps (e.g., masking, implanting, and heating steps) that are used to form the P-type base region of an NPN bipolar junction transistor in BiCMOS processes. Alternatively, P-base region 60 may be formed using process steps (e.g., masking, implanting, and heating) that are also used to form a P-well body region of an NMOS transistor in CMOS or BiCMOS processes.

Sacrificial oxide layer 53 can be removed following the formation of P-base 60, and gate oxide layer 55 can be grown on substrate 52 as shown in FIG. 2F. Oxide layer 55 may be, for example, grown at a temperate of 1000° C. to a thickness in the range of 150-700 Å. A specific example is 350 Å thick.

Masking and implantation steps may be performed to form voltage threshold implants in the PMOS transistor of FIG. 2E and adjacent transistors to adjust the threshold level of the transistors. For example, P-type dopant may be implanted and driven into N-well 54 where the gate will be formed to lower the threshold voltage of the PMOS transistor. Voltage threshold implants may be formed before or after oxide layer 53 is removed, and they may be eliminated entirely, if desired. Voltage thresholds implants may, for example, be implanted at a dose in the range of 1×10¹¹ to 1×10¹² dopants per cm² using Boron B₁₁ (a P-type dopant) into N-well 54 to reduce the threshold voltage of the resulting PMOS transistor.

Polysilicon deposition can then be performed to form a gate layer on top of oxide layer 55. The polysilicon layer can be doped with an N-type dopant such as a Phosphorous or Arsenic implant, or using POCl₃ diffusion. Subsequently, the polysilicon layer can be masked using photoresist and etched to form gate layer 62 as shown in FIG. 2F. The photoresist can then be removed, and the wafer may be cleaned. If desired, gate layer 62 may comprise polycide, such as WSiₓ formed on polysilicon. The thickness of gate layer 62 may be, for example, in the range of 0.1 to 0.5 microns.

Referring now to FIG. 2G, photoresist layer 64 is deposited on top of wafer 52 to mask the formation of P-extension regions of the device. P-type dopant is then implanted into N-well 54 to form P-extension regions 66A-66B at an energy level that allows the implant to go through gate oxide layer 55, but does not penetrate through polysilicon gate 62. P-type dopant may, for example, be implanted at a dose in the range of 1×10¹²-2×10¹³ dopants/cm². Photoresist layer 64 is then removed, and the P-type implant dopants are driven into the wafer to form P-extension regions 66A and 66B on either side of gate 62 as shown in FIG. 2H. P-extension 66B on the drain side of gate 62 extends all the way to field oxide region 58B. If desired, photoresist layer 64 may be extended further to the left beyond region 58B so that P-extension 66B does not extend all the way to oxide 58B.

P-extension regions 66A-66B are self-aligned with gate 62. P-extension region 66B overlaps P-base 60 as shown in FIG. 2H. Therefore, P-extension 66B aligns the entire drain region including P-base 60 with gate 62. P-base 60 is spaced away from gate 62 as shown in FIG. 2H. P-extension 66B extends from P-base 60 to underneath gate 62.

Conformal oxide deposition can be performed to form an oxide layer on and around gate 62 using, for example, LP-CVD low temperature oxide (LTO), Tetraethyl-ortho-silicate (TEOS), or TEOS/O₃ oxide. The ratio of conformal oxide deposition on the vertical features compared to the horizontal features is preferably greater than %50. An anisotropic dry etch can then be performed removing portions of the oxide layer on top of gate 62, oxide layer 55, and regions 58A-58C. Oxide spacers 68A and 68B are left next to gate layer 62 as shown in FIG. 2I after the anisotropic etch.

Photoresist can be redeposited on top of the structure in FIG. 2I to mask the formation of a highly doped N-type N-well contact region. N-type dopants are then implanted into the wafer. For example, Arsenic may be implanted at a dose in the range of 1×10¹⁵ to 1×10¹⁶ dopants/cm² at an energy level in the range of 50 to 180 KeV. The photoresist may then be removed. The N+ dopants are then driven into the wafer to form N+ contact region 69. N+ contact region 69 forms a low resistance contact to N-well 54 which is the body region of the PMOS transistor. N+ source and drain regions for adjacent NMOS transistors may be formed at the same time region 69 is formed using the same steps.

Photoresist can be redeposited on top of the structure in FIG. 2I to mask the formation of highly doped P-type source and drain contact regions. P-type dopant is implanted into the wafer to form these highly doped contacts. For example, the P-type dopant may be Boron B₁₁ or BF₂ implanted at a dose in the range of 1×10¹⁵ to 1×10¹⁶ dopants/cm² with an energy in the range of 30 to 100 KeV for BF₂ or 5 to 20 KeV for B₁₁. The photoresist may then be removed. The P-type dopant is then driven into the wafer to form P+ contact regions 70A and 70B as shown in FIG. 2J. The P-type dopant used to form regions 70A-70B may, for example, be diffused to a depth in the range of 0.2 to 0.7 microns. P-extension region 66B of the drain preferably extends from underneath the right portion of gate 62 at least to P+ contact region 70B. If desired, P-extension 66B may extend beyond P+ region 70B to oxide 58B. If desired, a P+ substrate contact region may be formed along with regions 70A-70B using the same steps.

A further optional feature includes P-type low doped drain regions (PLDD). Masking, implantation, and heating steps may be performed to form a PLDD region on the source side of gate 62 before conformal oxide deposition discussed above in FIG. 2I. If desired, a PLDD region may be formed in the drain offset to the right from gate 62. The mask used to form P+ regions 70A-70B may also be used to form the PLDD regions. The source side PLDD diffuses further under gate 62, because it is formed before oxide spacer 68A. N-type low doped drain regions may also be formed in NMOS transistors at the same time as the PLDD regions. The PLDD regions may be eliminated, if desired.

The structure of FIG. 2J is a PMOS transistor. Layer 62 is the gate of the transistor. P-type regions 66A and 70A form the source of the transistor. P-type regions 60, 66B, and 70B form the drain of the transistor. N-well region 54 is the body of the transistor. P+ contact regions 70A and 70B form low resistance electrical contacts to the source and the drain of the PMOS transistor, respectively.

The electric field on the gate side of the drain is typically larger than in other parts of the drain region when a voltage is applied between the gate and the drain. The large electric field can cause breakdown between the body and the gate side of the drain. When breakdown occurs between the drain and the body, unregulated current can flow between the body and the drain. High voltage transistors generally require a high breakdown voltage threshold so that breakdown does not occur at high operating voltages.

P-extension 66B overlaps P-base 60. P-extension region 66B also extends beyond P-base 60 underneath gate 62 as shown in FIG. 2J. A region of silicon that has a low doping concentration generally has a higher breakdown voltage than a region of silicon that has a higher doping concentration. The P-type doping concentration in the portion of P-extension region 66B extending under gate 62 beyond P-base region 60 is less than the P-type doping concentration in P-base region 60.

Therefore, the portion of P-extension 66B near gate 62 provides a higher breakdown voltage between the drain and the body of the transistor, than if P-extension region 66B was not in the transistor at all. It is particularly advantageous to have a lower doping concentration in the portion of the drain nearest to the gate, because the electric field is higher in this portion of the drain at high operating voltages making breakdown more likely than in other regions of the drain.

P-base 60 is offset to the right of gate 62 by a small distance in FIG. 2J so as not to increase the breakdown voltage. P-base 60 is also preferably offset to the right of spacer 68B by a small distance as shown in FIG. 2J. If desired, P-type low doped drain region implants may be diffused between gate 62 and P-base 60.

P-base region 60 extends deeper into N-well 54 than P+ drain contact region 70B, such that the drain-to-body PN junction is between P-base region 60 and N-well 54. P-base 60 provides a higher breakdown voltage at the drain-to-body PN junction of the PMOS transistor of FIG. 2J than would be the case if the drain-to-body PN junction where between regions 70B and 54. This is because P-base region 60 has a lower P-type doping concentration below P+ region 70B than P+ region 70B itself. P-base region 60 also increases the breakdown voltage of the PMOS transistor of FIG. 2J, because it has a larger radius of curvature than P-extension 66B and P+ region 70B. P-base 60 has a larger radius of curvature, because it diffuses into a larger volume than P-extension 66B and P+ region 70B.

A region of silicon with a greater net concentration of dopants typically has a higher conductivity and a lower resistance than a lower doped region, because of the presence of additional charge carriers. The area where regions 66B and 60 overlap has a higher net P-type doping concentration than in non-overlapping portions of regions 66B and 60. The overlapping area of regions 66B and 60 has a lower specific ON resistance, due to the higher P-type doping concentration in this area. Thus, the drain-to-source ON resistance of the PMOS transistor of FIG. 2J is reduced as result of the combination of the P-base and the P-extension regions of the drain.

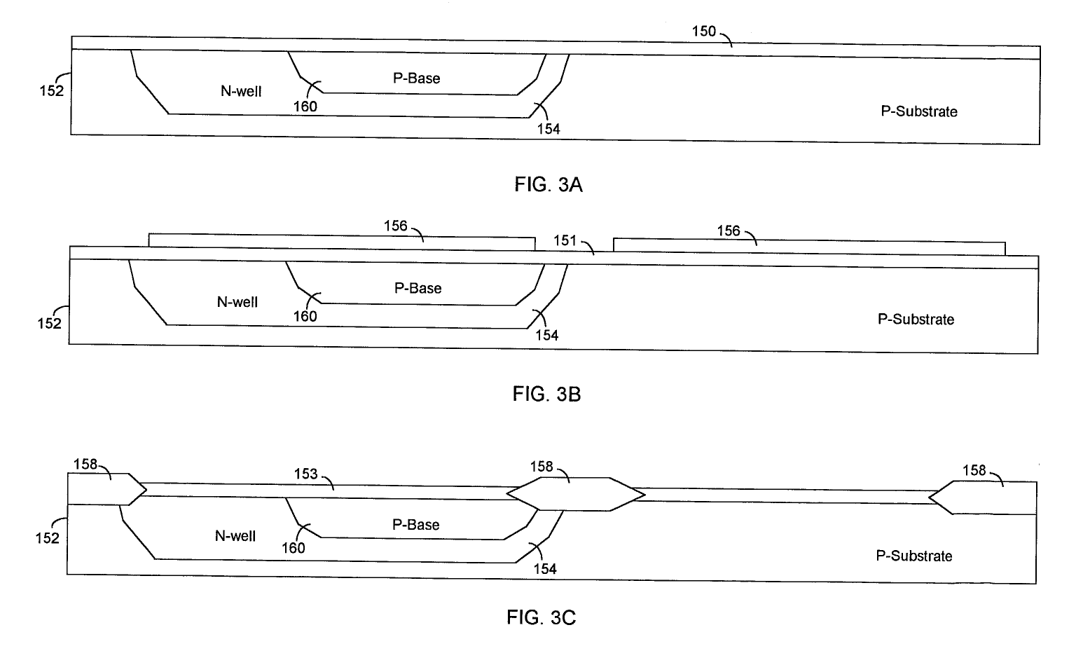

FIGS. 3A-3C are process steps for the fabrication of a second illustrative embodiment of high voltage PMOS transistors of the present invention. In the embodiment of FIGS. 3A-3C, the P-base region is formed before the field oxide regions. Referring first to FIG. 3A, N-well 154 can be formed in substrate 152 which has oxide layer 150 as discussed above with respect to FIGS. 2A-2E. P-base region 160 can be formed in N-well 154 as shown in FIG. 3A prior to the formation of field oxide regions. P-type dopant is implanted into the substrate, and a thermal anneal step is then performed so that the P-type dopant diffuses down into N-well 154 to form P-base region 160. For example, the anneal may be performed at a temperature in the range of 800 to 1500° C. for 30 minutes in ambient Nitrogen gas.

Oxide layer 150 can then be removed from P-type substrate 152, and oxide layer 151 can be grown on top of substrate 152. Subsequently, silicon nitride can be deposited on top of oxide layer 151 to mask the formation of thick field oxide regions 158. The silicon nitride is then masked and etched to form regions 156 as shown in FIG. 3B. LOCOS is then performed to grow field oxide regions 158 as shown in FIG. 3C and as discussed above with respect to FIGS. 2C-2D. Regions 158 may provide isolation between transistors in substrate 152. A sacrificial oxide layer 153 (e.g., 550 Å) is then grown on top of substrate 152. A gate, P-extension regions for the source and the drain, and P+ contact regions for the source and the drain can then be formed to create a PMOS transistor as discussed above.

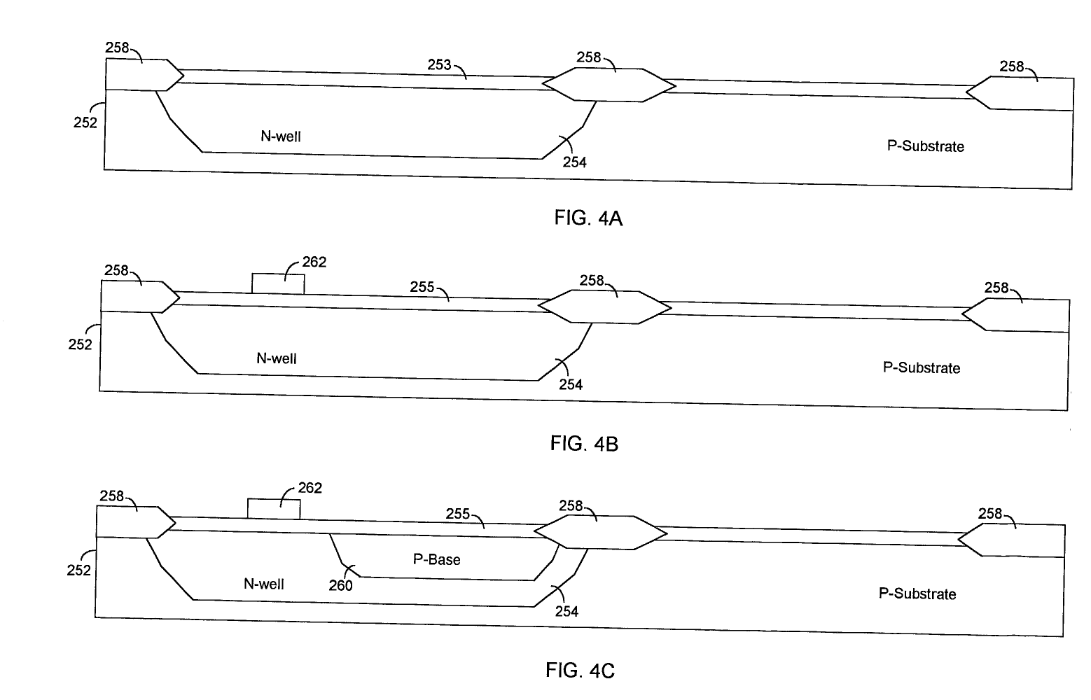

FIGS. 4A-4C are process steps for the fabrication of a third illustrative embodiment of high voltage PMOS transistors of the present invention. In the embodiment of FIGS. 4A-4C, the gate is formed before the P-base region. Referring to FIG. 4A, N-well 254, oxide regions 258, and sacrificial oxide layer 253 can be formed as discussed above with respect to the previous embodiments. Oxide layer 253 can then be removed, and gate oxide layer 255 is grown on top of P-type substrate 252. Polysilicon deposition and doping, followed by gate masking, etching, and photoresist removal, are then performed to form gate 262 of the PMOS transistor as shown in FIG. 4B.

A masking step may then be preformed to form P-base region 260 (e.g., using photoresist). P-type dopant may then be implanted into N-well 254 to form P-base region 260. The photoresist may then be removed. The P-type dopant is then driven into N-well 254 to from P-base 260. P-extension regions for the source and the drain, and P+ contact regions for the source and the drain can then be formed to create a PMOS transistor as discussed above.

In a further embodiment, PMOS transistors of the present invention may be formed in a N-type semiconductor substrate. In this embodiment, there is no need to form an N-well region such as region 54, because the substrate is N-type. P-base region 60, P-extension regions 66A-66B, and P+ regions 70A-70B are formed in the N-substrate. NMOS transistors may be fabricated in the same N-substrate. P-type wells may be deposited in the N-substrate, and NMOS transistors can be fabricated in the P-type wells. PMOS transistors of the present invention may also be formed in an N-type epitaxial layer.

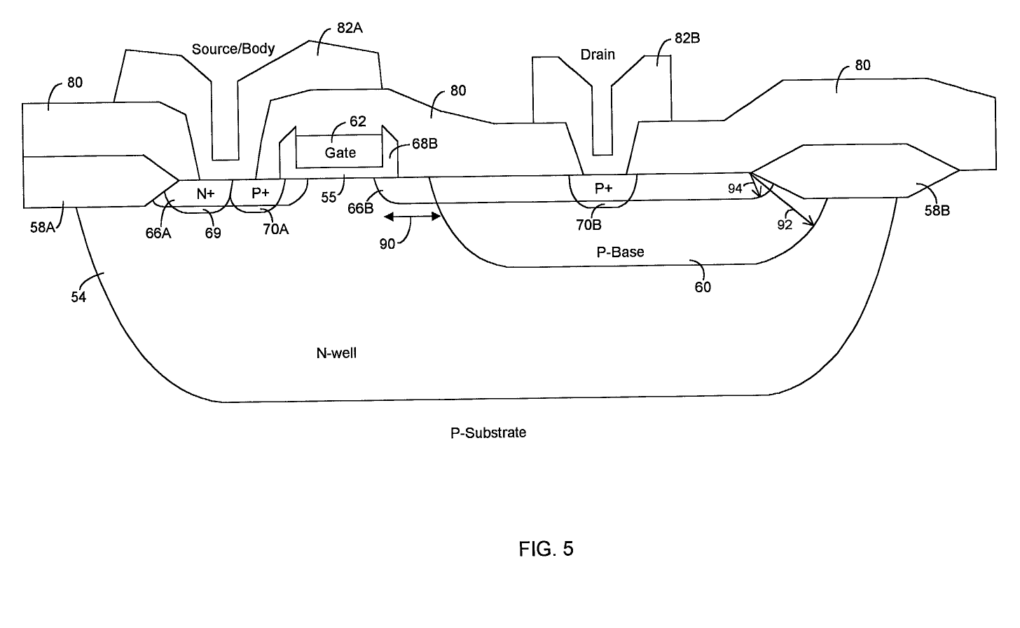

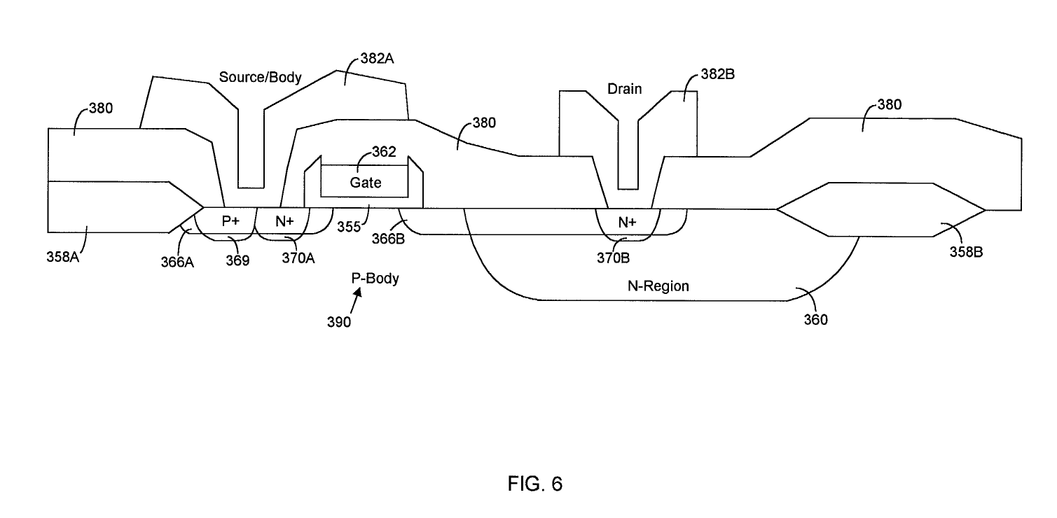

A PMOS transistor formed in accordance with the principles of the present invention is shown in FIG. 5. The PMOS transistor of FIG. 5 includes gate 62, N-well 54, P-base 60, P− source extension region 66A, P− drain extension region 66B, P+ source contact region 70A, P+ drain contact region 70B, N+ body contact region 69, and gate oxide 55. Gate oxide 55 can be etched away to expose the surfaces of the source and the drain regions as shown in FIG. 5.

A diffused region of semiconductor typically has curved lateral edges. For example, P-base region 60 and P-extension 66B have curved edges underneath oxide region 58B. The radius of curvature of P-base region 60 is indicated by arrow 92, and the radius of curvature of P-extension region 66B is indicated by arrow 94. Thus, it can be seen from FIG. 5 that the radius of curvature 92 of region 60 is larger than the radius of curvature 94 of region 66B. The larger radius of curvature of P-base 60 increases the breakdown voltage.

Dielectric layer 80 can then be formed on top of the PMOS transistor. Dielectric 80 may comprise, for example, borophosphosilicate glass (BPSG). Dielectric layer 80 can be etched down to surface of the source and drain regions. A metal layer can then be deposited on dielectric 80 and etched to form metal contacts 82A and 82B shown in FIG. 5. Metal contact 82A electrically contacts the source of the PMOS transistor at P+ region 70A and the body of the PMOS transistor at N+ region 69. A portion of metal contact 82A may overlap the gate and the drain. Metal contact 82B contacts the drain of the PMOS transistor at P+ region 70B.

In an MOS transistor, the electric field in the channel of the transistor caused by the voltage applied to the gate can cause unwanted charge carrier generation. These unwanted charge carriers can flow as a current into the substrate or into the gate. When charge becomes embedded in the gate oxide, the threshold voltage of the transistor changes which is undesirable.

Charge carrier generation caused by an electric field is less in a region of silicon that has a lower doping concentration. P-extension region 66B of the drain near gate 62 has a relatively low P-type doping concentration which advantageously reduces carrier generation in that portion of the drain causing a lower substrate current and a lower gate current. However, the specific ON resistance in the drain increases as the P-type doping concentration implanted into P-extension region 66B is decreased, undesirably increasing the drain-to-source ON resistance of the transistor. Therefore, both these factors should be taken into consideration when selecting the P-type doping concentration implanted into region 70B.

The following examples are provided as illustrative values. Other values may be used as well. In a PMOS transistor that comprises P-base region 60 and P-extension regions 70A-70B in which P-type dopant such as Boron is implanted into P-substrate 52 to form P-extension regions 70A-70B at a dose of 3×10¹² dopants/cm², the breakdown voltage between the drain and the source is 55 volts, the specific ON resistance of the drain is about 0.69 ohm-mm², and the current into the substrate remains below 1% of the drain current for drain-to-source voltages up to about 45 volts. In a PMOS transistor that comprises P-base region 60 and P-extension regions 70A-70B in which P-type dopant such as Boron is implanted into P-substrate 52 to form P-extension regions 70A-70B as a dose of 4×10¹² dopants/cm², the breakdown voltage between the drain and the source is 54 volts, the specific ON resistance in the drain is about 0.59 ohm-mm², and the current into the substrate remains below 1% of the drain current for drain-to-source voltages up to about 30 volts.

Substrate currents above 1% typically cause unacceptable parasitic effects. These example values illustrate that the drain-to-source voltage at which the substrate current increases to an undesirable value decreases substantially as the doping concentration implanted into the P-extension regions is increased. Thus, increasing the doping concentration in the P-extension regions reduces the specific ON resistance in the drain, but can greatly reduce the drain-to-source voltage at which the substrate current rises to an unacceptable level.

P-base region 60 may, for example, have a depth of about 1 micron, and the P-type dopant diffused into P-base region 60 may have a sheet resistance in the range of 2-3 kΩ per square (i.e., approximately 0.2 Ω-cm resistivity). These numbers yield a drain-to-source breakdown voltage of about 50 volts in a standard N-well. P-base region 60 is aligned with respect to gate 62. For P-base region that is X microns deep, lateral distance 90 (FIG. 5) between the gate and P-base region 60 may be X+3D, where 3D represents 3 alignment standard deviations. For example, for a 1 micron deep P-base region 60 using a 1X G-line stepper (UltraTech Stepper), the minimum value of distance 90 is 1.75 microns. For a 0.6 micron deep P-base region 60 using a 5X I-line stepper (ASM Stepper), the minimum value of distance 90 is 1.0 micron. The ratio between the depth of P-base 90 and lateral distance 90 may be, for example, between 1.5 and 1.8. P-base region 60 may also be offset to the right of spacer 68B as shown in FIG. 5.

The present invention also includes NMOS transistors. An example of an NMOS transistor of the present invention is shown in FIG. 6. The NMOS transistor of FIG. 6 includes gate 362, gate oxide 355, P-type body 390, N-type region 360, N-type extension 366A of the source, N-type extension 366B of the drain, highly doped N+ source contact 370A, highly doped N+ drain contact 370B, highly doped P+ body contact 369, oxide field regions 358A-358B, dielectric layer 380, source contact 382A, and drain contact 382B.

These layers and regions may be formed using the process steps discussed above with appropriate dopants and dopant concentrations. Dopant implanted to form N-region 360 has a lower N-type doping concentration than dopant implanted to form N+ region 370B. Dopant implanted to form N-region 360 has a greater N-type doping concentration than dopant implanted to form N-extension 366B. N-region 360 and N-extension 366B provide an increased breakdown voltage and a reduced specific ON resistance as discussed above with respect to PMOS embodiments.

N-region 360 may be formed using process steps (e.g., masking, implanting, and heating steps) that are used to form an N-type base region of a PNP bipolar junction transistor. Alternatively, N-region 360 may be formed using process steps that are also used to form an N-well body region of a PMOS transistor in CMOS or BiCMOS processes. For example, the formation of one type of N-well body region of a PMOS transistor is discussed above with respect to FIGS. 2A-2B. P-body 390 may be a P-type substrate, a P-well region, or a P-type epitaxial layer. P-extension 366B extends from region 370B to under gate 362. If desired, P-extension 366B may extend all the way to the edge of field oxide region 358B.

Persons skilled in the art further will recognize that the circuitry of the present invention may be implemented using structures and process steps other than those shown and discussed above. All such modifications are within the scope of the present invention, which is limited only by the claims which follow.

What is claimed is:

1. An integrated circuit having a high voltage MOS transistor, the high voltage MOS transistor comprising:
a body in a region of semiconductor;
a gate above the body; and
a drain and a source formed in the region of semiconductor, wherein the drain comprises:
a first drain region that has a first concentration of dopant, a first depth, and a first radius of curvature,
a second drain region that has a second concentration of dopant that is less than the first concentration of dopant, a second depth greater than the first depth, and a second radius of curvature greater than the first radius of curvature, and
a third drain region extending from the second region to the gate that has a third concentration of dopant that is less than the second concentration of dopant, and a third radius of curvature that is less than the second radius of curvature.

2. The integrated circuit of claim 1 wherein the MOS transistor is a PMOS transistor, the body comprises N-type dopant, the source comprises P-type dopant, and the first, second, and third concentrations of dopant in the drain comprise P-type dopant.

3. The integrated circuit of claim 2 wherein dopant is implanted at a concentration of between 5×10¹² and 6×10¹³ dopants per cm² into the body region to form the second region of the drain.

4. The integrated circuit of claim 2 wherein dopant is implanted at a concentration of between 1×10¹² and 2×10¹³ dopants per cm² into the body region to form the third region of the drain.

5. The integrated circuit of claim 2 wherein dopant is implanted at a concentration of between 1×10¹⁵ and 1×10¹⁶ dopants per cm² into the second region of the drain to form the first region of the drain.

6. The integrated circuit of claim 1 wherein the MOS transistor is a NMOS transistor, the body comprises P-type dopant, the source comprises N-type dopant, and the first, second, and third concentrations of dopant in the drain comprise N-type dopant.

7. The integrated circuit of claim 1 wherein the MOS transistor is a PMOS transistor, and the second region of the drain is formed from process steps that can be used to form a base of an NPN bipolar transistor.

8. The integrated circuit of claim 1 wherein the MOS transistor is an NMOS transistor, and the second region of the drain is formed from process steps that can be used to form a base of an PNP bipolar transistor.

9. The integrated circuit of claim 1 wherein the second region of the drain is formed before the first and third regions of the drain.

10. The integrated circuit of claim 9 wherein the third region of the drain is formed before the first region of the drain.

11. The integrated circuit of claim 1 wherein the second region of the drain is formed before the gate.

12. The integrated circuit of claim 1 wherein the gate is formed before the first, second, and third regions of the drain.

13. The integrated circuit of claim 1 wherein the source comprises:
a first region with a first doping concentration that extends under the gate; and
a second region with a second doping concentration that is greater than the first doping concentration in the first source region.

14. The integrated circuit of claim 1 wherein the ratio of the second depth of the second drain region to a lateral distance between the gate and the second drain region is between 1.5 and 1.8.

15. The integrated circuit of claim 1 further comprising an oxide spacer on the drain side of the gate, wherein the second region of the drain is offset from the drain side spacer by a distance greater than zero.

16. The integrated circuit of claim 1 wherein the second region of the drain is formed from process steps that can also be used to form a body region of an MOS transistor.

17. A method for making an integrated circuit with a high voltage MOS transistor that includes a source and a gate, the method comprising:
implanting and diffusing a first concentration of dopant into a region of semiconductor to a first depth to form a first drain region;
implanting and diffusing a second concentration of dopant that is lower than the first concentration of dopant into the region of semiconductor to form a second drain region that overlaps the first drain region and extends beyond the first drain region under the gate of the transistor; and
implanting and diffusing a third concentration of dopant that is higher than the first concentration of dopant into the first drain region to a second depth less than the first depth to form a third drain region.

18. The method of claim 17 wherein the MOS transistor is an NMOS transistor.

19. The method of claim 18 wherein implanting and diffusing the first concentration of dopant comprises a process step that can be used to form a base of a PNP bipolar transistor.

20. The method of claim 17 wherein the MOS transistor is a PMOS transistor.

21. The method of claim 20 wherein implanting and diffusing the first concentration of dopant comprises a process step that can be used to form a base of an NPN bipolar transistor.

22. The method of claim 20 wherein P-type dopant is implanted at a concentration of between 5×10¹² and 6×10¹³ dopants per cm² into the region of semiconductor to form the first drain region.

23. The method of claim 20 wherein P-type dopant is implanted at a concentration of between 1×10¹² and 2×10¹³ dopants per cm² into the region of semiconductor to form the second drain region.

24. The method of claim 20 wherein P-type dopant is implanted at a concentration of between 1×10¹⁵ and 1×10¹⁶ dopants per cm² into the first drain region to form the third drain region.

25. The method of claim 17 wherein the first drain region is formed before the gate.

26. The method of claim 17 wherein the gate is formed before the first, second, and third drain regions.

27. The method of claim 17 wherein the ratio of the first depth to a lateral distance between the gate and the first drain region is between 1.5 and 1.8.

28. The method of claim 17 wherein an oxide spacer is formed on the drain side of the gate, and the first drain region is offset from the drain side spacer by a distance greater than zero.

29. The method of claim 17 wherein the first drain region has a radius of curvature that is larger than a radius of curvature of the second drain region and a radius of curvature of the third drain region.

30. A method for making an integrated circuit with a high voltage MOS transistor, the method comprising:
implanting and diffusing a first concentration of dopant into semiconductor to a first depth to form a first drain region;
forming a gate over a body region of the semiconductor;
implanting and diffusing a second concentration of dopant that is lower than the first concentration of dopant into the semiconductor to form a first source region and a second drain region, wherein the second drain region overlaps the first drain region and extends beyond the first drain region under the gate; and
implanting and diffusing a third concentration of dopant that is higher than the first concentration of dopant into the first source region and the first drain region to a second depth that is less than the first depth to form a second source region and a third drain region.

31. The method of claim 30 wherein the MOS transistor is an NMOS transistor.

32. The method of claim 31 wherein implanting and diffusing the first concentration of dopant comprises process steps that can be used to form a base of a PNP bipolar transistor.

33. The method of claim 30 wherein the MOS transistor is a PMOS transistor.

34. The method of claim 33 wherein implanting and diffusing the first concentration of P-type dopant comprises process steps that can be used to form a base of an NPN bipolar transistor.

35. The method of claim 33 wherein P-type dopant is implanted at a concentration of between 5×10¹² and 6×10¹³ dopants per cm² into the region of semiconductor to form the first drain region.

36. The method of claim 33 wherein P-type dopant is implanted at a concentration of between 1×10¹² and 2×10¹³ dopants per cm² into the region of semiconductor to form the second drain region.

37. The method of claim 33 wherein P-type dopant is implanted at a concentration of between 1×10¹⁵ and 1×10¹⁶ dopants per cm² into the first drain region to form the third drain region.

38. The method of claim 30 wherein the ratio of the first depth to a lateral distance between the gate and the first drain region is between 1.5 and 1.8.

39. The method of claim 30 further comprising forming an oxide spacer on the drain side of the gate; and wherein the first drain region is offset from the drain oxide side spacer by a distance greater than zero.

40. The method of claim 30 wherein the first drain region has a radius of curvature that is larger than a radius of curvature of the second drain region and a radius of curvature of the third drain region.

41. A method for making an integrated circuit with a high voltage MOS transistor, the method comprising:
forming a gate over a body region of semiconductor;
implanting and diffusing a first concentration of dopant into the semiconductor to a first depth to form a first drain region;
implanting and diffusing a second concentration of dopant that is lower than the first concentration of dopant into the semiconductor to form a first source region and a second drain region, wherein the second drain region overlaps the first drain region and extends laterally beyond the first drain region under the gate; and
implanting and diffusing a third concentration of dopant that is higher than the first concentration of dopant into the first source region and the first drain region to a second depth that is less than the first depth to form a second source region and a third drain region.

42. The method of claim 41 wherein the MOS transistor is an NMOS transistor.

43. The method of claim 42 wherein implanting and diffusing the first concentration of dopant comprises process steps that can be used to form a base of a PNP bipolar transistor.

44. The method of claim 41 wherein the MOS transistor is a PMOS transistor.

45. The method of claim 44 wherein implanting and diffusing the first concentration of dopant comprises process steps that can be used to form a base of an NPN bipolar transistor.

46. The method of claim 44 wherein P-type dopant is implanted at a concentration of between 5×10¹² and 6×10¹³ dopants per cm² into the region of semiconductor to form the first drain region.

47. The method of claim 44 wherein P-type dopant is implanted at a concentration of between 1×10¹² and 2×10¹³ dopants per cm² into the region of semiconductor to form the second drain region.

48. The method of claim 44 wherein P-type dopant is implanted at a concentration of between 1×10¹⁵ and 1×10¹⁶ dopants per cm² into the first drain region to form the third drain region.

49. The method of claim 44 wherein the body region of the semiconductor comprises an N-well region formed in a P-type semiconductor substrate.

50. The method of claim 41 wherein the ratio of the first depth to a lateral distance between the gate and the first drain region is between 1.5 and 1.8.

51. The method of claim 41 further comprising forming an oxide spacer on the drain side of the gate; and wherein the first drain region is offset from the drain side oxide spacer by a distance greater than zero.

52. The method of claim 41 wherein the first drain region has a radius of curvature that is larger than a radius of curvature of the second drain region and a radius of curvature of the third drain region.

53. A high voltage MOS transistor comprising:
a gate;
a source;
a body; and
a drain comprising:
means for providing a first doping concentration in a first portion of the drain to decrease resistance in the drain,
means for providing a second doping concentration in a second portion of the drain extending below the first portion to increase a breakdown voltage between the drain and the body, and
means for providing a third doping concentration in a third portion of the drain between the gate and the first portion of the drain to increase the breakdown voltage.

54. The high voltage MOS transistor of claim 53 wherein the MOS transistor is an NMOS transistor.

55. The high voltage MOS transistor of claim 54, wherein the second doping concentration is formed using comprises process steps that can be used to form a base of a PNP bipolar transistor.

56. The high voltage MOS transistor of claim 53 wherein the MOS transistor is a PMOS transistor.

57. The high voltage MOS transistor of claim 56 wherein the second doping concentration is formed using process steps that can be used to form a base of an NPN bipolar transistor.

58. The high voltage MOS transistor of claim 56 wherein P-type dopant is implanted at a concentration of between 5×10¹² and 6×10¹³ dopants per cm² to form the second portion of the drain.

59. The high voltage MOS transistor of claim 56 wherein P-type dopant is implanted at a concentration of between 1×10¹² and 2×10¹³ dopants per cm² to form the third portion of the drain.

60. The high voltage MOS transistor of claim 56 wherein P-type dopant is implanted at a concentration of between 1×10¹⁵ and 1×10¹⁶ dopants per cm² to form the first portion of the drain.

61. The high voltage MOS transistor of claim 53 wherein the second doping concentration overlaps with the third doping concentration to decrease resistance in the drain.

62. The high voltage MOS transistor of claim 53 wherein the second portion of the drain is formed before the first and third portions of the drain.

63. The high voltage MOS transistor of claim 53 wherein the second portion of the drain is formed before the gate.

64. The high voltage MOS transistor of claim 53 wherein the gate is formed before the first, second, and third portions of the drain.

65. The high voltage MOS transistor of claim 53 wherein the source comprises:
a first region with a first doping concentration that extends under the gate; and
a second region with a second doping concentration that is greater than the first doping concentration of the first source region.

66. The high voltage MOS transistor of claim 53 wherein the second portion of the drain extends down into the region of semiconductor to a first depth, and the ratio of the first depth to a lateral distance between the gate and the second region of the drain is between 1.5 and 1.8.

67. The high voltage MOS transistor of claim 53 further comprising an oxide spacer on the drain side of the gate, wherein the second portion of the drain is offset from the drain side oxide spacer by a distance greater than zero.

68. The high voltage MOS transistor of claim 53 wherein the second portion of the drain has a radius of curvature that is larger than a radius of curvature of the first portion of the drain and a radius of curvature of the third portion of the drain.

69. An integrated circuit having a high voltage MOS transistor, the high voltage MOS transistor comprising:
a body in a region of semiconductor;
a gate above the body; and
a drain and a source formed in the region of semiconductor, wherein the drain comprises:
a first region that has a first concentration of dopant and a first radius of curvature,
a second region extending below the first region that has a second concentration of dopant that is less than the first concentration of dopant and a second radius of curvature greater than the first radius of curvature, wherein the second region of the drain is spaced away from the gate, and
a third region extending from the second region to the body underneath the gate that has a third concentration of dopant that is less than the second concentration of dopant.

70. A method for making an integrated circuit with a high voltage MOS transistor that includes a source and a gate, the method comprising:
implanting and diffusing a first concentration of dopant into a region of semiconductor to a first depth to form a first drain region that has a first radius of curvature, wherein the first drain region is spaced away from the gate;
implanting and diffusing a second concentration of dopant that is lower than the first concentration of dopant into the region of semiconductor to form a second drain region that overlaps the first drain region and extends beyond the first drain region to under the gate of the transistor; and
implanting and diffusing a third concentration of dopant that is higher than the first concentration of dopant into the first drain region to a second depth less than the first depth to form a third drain region, wherein the third drain region has a second radius of curvature less than the first radius of curvature.

71. A method for making an integrated circuit with a high voltage MOS transistor that includes a source and a gate, the method comprising:
implanting and diffusing a first concentration of dopant into a region of semiconductor to a first depth to form a first drain region that has a first radius of curvature, wherein the first drain region is spaced away from the gate and the ratio of the first depth to a lateral distance between the gate and the first drain region is between 1.5 and 1.8;
implanting and diffusing a second concentration of dopant that is lower than the first concentration of dopant into the region of semiconductor to form a second drain region that overlaps the first drain region and extends beyond the first drain region to under the gate of the transistor; and
implanting and diffusing a third concentration of dopant that is higher than the first concentration of dopant into the first drain region to a second depth less than the first depth to form a third drain region, wherein the third drain region has a second radius of curvature less than the first radius of curvature.

72. The method of claim 71 wherein the first depth equals 1 micron.

73. An integrated circuit having a high voltage PMOS transistor, the high voltage PMOS transistor comprising:
a N-type body in a region of semiconductor;
a gate above the N-type body; and
a P-type drain and a P-type source formed in the region of semiconductor, wherein the P-type drain comprises:
a first region that has a first concentration of P-type dopant,
a second region extending below the first region that has a second concentration of P-type dopant that is less than the first concentration of P-type dopant, and
a third region extending from the second region to under the gate that has a third concentration of P-type dopant that is less than the second concentration of P-type dopant.

74. An integrated circuit having a high voltage PMOS transistor, the high voltage PMOS transistor comprising:
an N-type body in a region of semiconductor;
a gate above the N-type body; and
a P-type drain and a P-type source formed in the region of semiconductor, wherein the drain comprises:
a first drain region that has a first concentration of dopant, a first depth, and a first radius of curvature,
a second drain region that has a second concentration of dopant that is less than the first concentration of dopant, a second depth greater than the first depth, and a second radius of curvature greater than the first radius of curvature, and
a third drain region extending from the second region to the gate that has a third concentration of dopant that is less than the second concentration of dopant, and a third radius of curvature that is less than the second radius of curvature.

75. An integrated circuit having a high voltage PMOS transistor, the high voltage PMOS transistor comprising:
an N-type body in a region of semiconductor;
a gate above the N-type body; and
a P-type drain and a P-type source formed in the region of semiconductor, wherein the drain comprises:
a first drain region that has a first concentration of dopant and a first radius of curvature,
a second drain region extending below the first region that has a second concentration of dopant that is less than the first concentration of dopant and a second radius of curvature greater than the first radius of curvature, wherein the second region of the drain is spaced away from the gate, and
a third drain region extending from the second region to the body underneath the gate that has a third concentration of dopant that is less than the second concentration of dopant.
